(19) United States
(12) Patent Application Publication
(10) Pub. No.: US 2021/0378093 A1
(43) Pub. Date: Dec. 2, 2021

(54) DISPLAY SCREEN, SPLICED DISPLAY SCREEN, AND SPLICING METHOD FOR SPLICED DISPLAY SCREEN

(71) Applicant: CHONGQING KONKA PHOTOELECTRIC TECHNOLOGY RESEARCH INSTITUTE CO., LTD., Chongqing (CN)

(72) Inventor: Shi Song ZHENG, Chongqing (CN)

(21) Appl. No.: 17/362,192

(22) Filed: Jun. 29, 2021

Related U.S. Application Data
(63) Continuation of application No. PCT/CN2020/093011, filed on May 28, 2020.

(51) Int. Cl. H05K 1/02

(52) U.S. Cl. CPC H05K 1/0296; H05K 2201/10128; H05K 1/028

(57) ABSTRACT

A display screen, a spliced display screen, and a splicing method for the spliced display screen are provided. The display screen includes a substrate and at least one first flexible printed circuit FPC. The substrate is provided with at least one set of first signal lines on a side edge of the substrate, where each set of first signal lines is coupled with a first connecting portion of a corresponding first FPC, and for each first FPC, a second connecting portion of the first FPC faces the side edge of the substrate where the at least one set of first signal lines is disposed.

### CROSS-REFERENCE TO RELATED APPLICATION(S)

This application is a continuation of International application No. PCT/CN2020/093011, filed on May 28, 2020, the disclosure of which is hereby incorporated by reference in its entirety.

### TECHNICAL FIELD

This disclosure relates to the technical field of display screens, and more particularly to a display screen, a spliced display screen adopting the display screen, and a splicing method for the spliced display screen.

### BACKGROUND

Spliced display screens are suitable for large-size display screens, which are widely used in information display terminals at the airport, port, wharf, subway, highway, or other places. It is apparent that the spliced display screen is formed by splicing multiple display screens. The display screen and a control terminal are generally coupled with each other through a flexible printed circuit (FPC). The existing display screen for splicing is only provided with signal lines and FPCs on one side of the display screen, where the display screen is coupled with printed circuit boards via the FPCs. However, in the above manner, communication between adjacent display screens cannot be realized, and it is also difficult to realize line layout in large-size and super-size spliced display screens. When more than three rows of display screens are spliced, there will be a large gap between the middle display screen and adjacent display screens, resulting in poor effect of the whole spliced display screen.

### SUMMARY

To solve the problem that there is a large gap between adjacent display screens and data transmission between the two adjacent display screens cannot be realized during splicing the existing display screens, implementations of the disclosure provide a display screen, a splice display screen, and a splicing method for the spliced display screen, in which the gap among the display screens may be small and the data transmission among the multiple display screens can be realized, during splicing of the display screens.

To achieve the above method, according to one aspect, a display screen is provided. The display screen includes a substrate and at least one first flexible printed circuit (FPC). The substrate is provided with at least one set of first signal lines on a side edge of the substrate, wherein each set of first signal lines is coupled with a first connecting portion of a corresponding first FPC, and for each first FPC, a second connecting portion of the first FPC faces the side edge of the substrate where the at least one set of first signal lines is disposed.

In at least one implementation, the first FPC has a U shape.

In at least one implementation, the first FPC has a semicircular shape.

In at least one implementation, the first FPC has a semi-rectangular shape.

In at least one implementation, the substrate is provided with at least one set of second signal lines on another side edge of the substrate opposite to the side edge where the at least one set of first signal lines is disposed, where the at least one set of second signal lines is coupled with at least one second FPC, and for each second FPC, the second FPC has a first connecting portion coupled with a corresponding set of second signal lines and a second connecting portion facing the another side edge of the substrate where the at least one set of second signal lines is disposed.

In one example, the second FPC has a same shape as the first FPC.

In at least one implementation, for each set of first signal lines, a central axis of a line-outlet position of the set of first signal lines and a central axis of a line-outlet position of the at least one set of second signal lines are parallel to one another.

In at least one implementation, for each second FPC, a central axis of the second connecting portion of the second FPC coincides with that of the second connecting portion of one of two first FPCs adjacent to the second FPC.

According to another aspect, implementations of the disclosure further provide a spliced display screen. The spliced display screen includes two display screens described above. For each display screen, the display screen includes at least one first flexible printed circuit (FPC), at least one second FPC, and a substrate, where the substrate is provided with at least one set of first signal lines on a side edge of the substrate and at least one set of second signal lines on another side edge of the substrate opposite to the side edge where the at least one set of first signal lines is disposed. Each set of first signal lines is coupled with a first connecting portion of a corresponding first FPC, and each set of second signal lines is coupled with a first connecting portion of a corresponding second FPC. For each first FPC, a second connecting portion of the first FPC faces the side edge of the substrate where the at least one set of first signal lines is disposed. For each second FPC, a second connecting portion of the second FPC faces the another side edge of the substrate where the at least one set of second signal lines is disposed. The at least one first FPC in one of the two display screens is electrically coupled to the at least one second FPC in the other of the two display screens.

According to another aspect, implementations of the disclosure further provide a splicing method for the spliced display screen. The method includes the following. For each of two display screens, the at least one first FPC and the at least one second FPC of the display screen are respectively bent toward a back surface of the display screen. A side edge of one of the two display screens on which the at least one set of first signal lines is disposed and a side edge of the other of the two display screens on which the at least one set of second signal lines is disposed are coupled together. The at least one first FPC of one of the at least two display screens and the at least one second FPC of another of the at least two display screens are electrically coupled to one another via at least one connecting device.

In at least one implementation, the at least one first FPC and the at least one second FPC of the display screen are bent to the back surface of the display screen by 180°.

Implementing the disclosure has the following technical effects. The at least one FPC is provided on one side edge of the substrate of the display screen. For each FPC, the FPC has one end coupled with a corresponding set of signal lines and the other end facing the side edge of the substrate where the at least one set of first signal lines is disposed. In this way, after the FPC is bent to the back surface of the substrate, during splicing of two display screens, the two adjacent FPC can be directly coupled to each other to realize data transmission between the adjacent display screens. Furthermore, it is easy to achieve line layout, and after the FPCs are folded, small gaps between the display screens can be achieved. By adopting the splicing method, at least two display screens are spliced, where each of the at least two display screens is provided with the above-mentioned FPCs on both side edges of the display screen, which can realize the data transmission between adjacent display screens and facilitate the layout of the lines to be suitable for large-size and super-size spliced display screens. In addition, after the FPCs are folded, small gaps or seamless splicing between the display screens can be achieved.

### BRIEF DESCRIPTION OF THE DRAWINGS

FIG. 1 is a structural view of a display screen according to implementations of the disclosure.

FIG. 2 is a structural view of a display screen according to other implementations of the disclosure.

FIG. 3 is a structural view of a display screen according to other implementations of the disclosure.

FIG. 4 is a structural view of a display screen according to other implementations of the disclosure.

FIG. 5 is a flow chart illustrating a splicing method for a spliced display screen according to implementations of the disclosure.

FIG. 6 is a structural view of a spliced display screen according to implementations of the disclosure.

Reference numbers in the figures are illustrated as follows.
10: substrate; 20, 21: signal line; 30, 31: flexible printed circuit (FPC).

### DETAILED DESCRIPTION

Technical solutions embodied in implementations of the disclosure will be described in a clear and comprehensive manner in conjunction with the accompanying drawings. It is evident that the implementations described herein are merely some rather than all the implementations of the disclosure. Based on the implementations of the disclosure, all other implementations obtained by those of ordinary skill in the art without creative work shall fall within the protection scope of the disclosure.

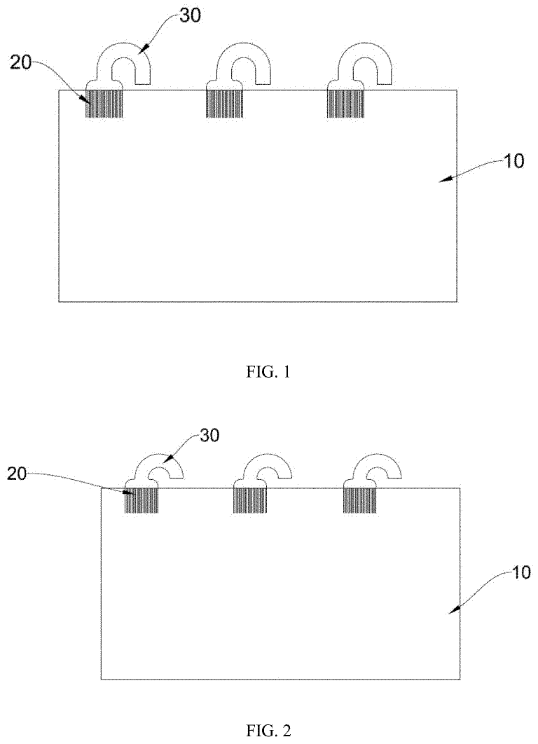

As illustrated in FIG. 1, a display screen is provided. The display screen includes a substrate 10. The substrate 10 is made of glass. A transparent conductive layer of indium oxide (In₂O₃) or stannic oxide (SnO₂), that is, an indium tin oxide (ITO) film layer, is formed on a surface of the glass by vapor deposition. The substrate 10 is provided with multiple sets of signal lines 20 on a side edge of the substrate 10. The multiple sets of signal lines 20 are evenly arranged and used for communication of the display screen. Each set of signal lines 20 is coupled with a corresponding flexible printed circuit (FPC) 30. The FPC is a highly reliable and excellent flexible printed circuit board made of polyimide or polyester film. The FPC has a high wiring density and is light, thin, and easy to be bent. Depending on those characteristics, for each FPC 30, a first connecting portion of the FPC 30 can be coupled to a corresponding set of signal lines 20, and a second connecting portion of the FPC 30 faces the side edge of the substrate 10 on which the multiple sets of signal lines 20 are disposed. In one example, as illustrated in FIG. 1, the FPC 30 is U-shaped. In this way, bend the whole U-shaped FPC from a side of the FPC close to a line end of the signal lines and after the whole U-shaped FPC is bent to a back surface of the display screen, another end of the FPC away from the signal lines still faces the side edge of the substrate where the multiple sets of signal lines are disposed. Therefore, after two same display screens are spliced together, all FPCs of the two display screens can be completely hidden on the back surface of the two display screens, such that the gap between the two display screens can be minimized, and even seamless splicing of the two display screens can be achieved. In addition, the FPCs of the two display screens can also be coupled to each other to realize mutual communication.

In at least one implementation, as illustrated in FIG. 2, a display screen is provided. The display screen includes a substrate 10. The substrate 10 is made of glass. A transparent conductive layer of In₂O₃ or SnO₂, that is, an ITO film layer, is formed on a surface of the glass by vapor deposition. The substrate 10 is provided with multiple sets of signal lines 20 on a side edge of the substrate 10. The multiple sets of signal lines 20 are evenly arranged and used for communication of the display screen. Each set of signal lines 20 is coupled with a corresponding FPC 30. The FPC is a highly reliable and excellent flexible printed circuit board made of polyimide or polyester film. The FPC has a high wiring density, and is light, thin, and easy to be bent. Depending on those characteristics, for each FPC 30, a first connecting portion of the FPC 30 can be coupled to a corresponding set of signal lines 20, and a second connecting portion of the FPC 30 faces the side edge of the substrate 10 on which the multiple sets of signal lines 20 are disposed. In one example, as illustrated in FIG. 2, the FPC 30 has a semicircular shape. In this way, bend the whole semicircular FPC from a side of the FPC close to a line end of the signal lines and after the whole semicircular FPC is bent to a back surface of the display screen, another end of the FPC away from the signal lines still faces the side edge of the substrate where the multiple sets of signal lines are disposed. Therefore, after two same display screens are spliced together, all FPCs of the two display screens can be completely hidden on the back surface of the two display screens, such that the gap between the two display screens can be minimized, and even seamless splicing of the two display screens can be achieved. In addition, the FPCs of the two display screens can also be coupled to each other to realize mutual communication.

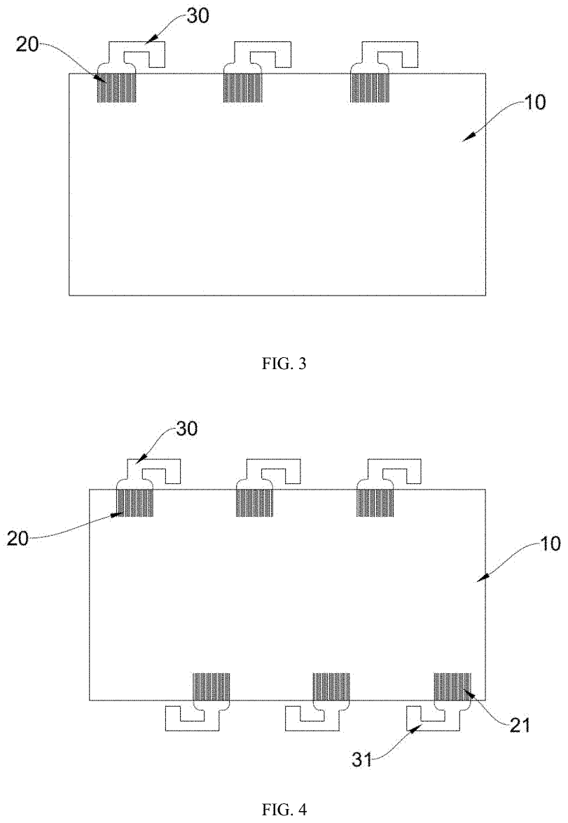

In at least one implementation, as illustrated in FIG. 3, a display screen is provided. The display screen includes a substrate 10. The substrate 10 is made of glass. A transparent conductive layer of In₂O₃ or SnO₂, that is, an ITO film layer, is formed on a surface of the glass by vapor deposition. The substrate 10 is provided with multiple sets of signal lines 20 on a side edge of the substrate 10. The multiple sets of signal lines 20 are evenly arranged, and used for communication of the display screen. Each set of signal lines 20 is coupled with a corresponding FPC 30. The FPC is a highly reliable and excellent flexible printed circuit board made of polyimide or polyester film. The FPC has a high wiring density, and is light, thin, and easy to be bent. Depending on those characteristics, for each FPC 30, a first connecting portion of the FPC 30 is coupled to a corresponding set of signal lines 20, and a second connecting portion of the FPC 30 faces the side edge of the substrate 10 on which the multiple sets of signal lines 20 are disposed. In one example, as illustrated in FIG. 3, the FPC 30 has a semi-rectangular shape. In this way, bend the whole semi-rectangular FPC from a side of the FPC close to a line end of the signal lines and after the whole semi-rectangular FPC is bent to a back surface of the display screen, another end of the FPC away from the signal lines still faces the side edge of the substrate where the multiple sets of signal lines are disposed. Therefore, after two same display screens are spliced together, all FPCs of the two display screens can be completely hidden on the back surface of the two display screens, such that the gap between the two display screens can be minimized, and even seamless splicing of the two display screens can be achieved. In addition, the FPCs of the two display screens can also be coupled to each other to realize mutual communication.

It should be noted that although the foregoing merely illustrates the above-mentioned three shapes of FPCs, there is no restriction on the shape of the FPC, that is, FPCs of other shapes, such as FPC of a parabolic shape, are also within the protection scope of the disclosure.

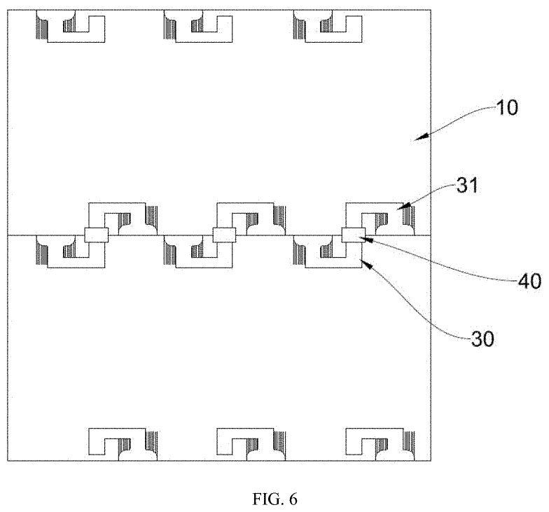

In at least one implementation, as illustrated in FIG. 4, the implementation illustrated in FIG. 4 is an improvement made on the basis of any of the above implementations. In the above implementations, FPCs are only disposed on one side of the display screen, while in the implementation illustrated in FIG. 4, FPCs are provided on both sides of the display screen. That is, multiple sets of signal lines 21 and the multiple sets of signal lines 20 are arranged on opposite sides of the display screen. Similarly, the multiple sets of signal lines 21 are evenly arranged on another side edge of the substrate 10, and used for the communication of the display screen. In one example, number of the multiple sets of signal lines 21 is the same as that of the multiple sets of signal lines 20. Each set of signal lines 21 is coupled with a corresponding FPC 31. The FPC 31 has a first connecting portion coupled with a corresponding set of signal lines 21 and a second connecting portion facing the side edge of the substrate where the multiple sets of signal lines 21 are disposed. To facilitate coupling of the FPCs of the two display screens during splicing, for each set of first signal lines, a central axis of a line-outlet position of the set of signal lines 20 and a central axis of a line-outlet position of each set of signal lines 21 are parallel to one another, that is, the signal lines on both side edges of the substrate 10 are staggered. Further, for each two sets of signal lines that are staggered, second connecting portions of two FPCs respectively connected to the two sets of signal lines directly face each other. In this way, when two same display screens are selected for splicing, assuming that one side of the display screen is defined as side A and the other side of the display screen is defined as side B, where positions of signal lines on side A of one of the two display screens (e.g., the first display screen) are the same as that of signal lines on side A of the other of the two display screens (e.g., the second display screen). During splicing of the two display screens, side A of the first display screen is connected to side B of the other display screen, and FPCs on side A and FPCs on side B are bent toward the back surface of the display screens. Since ends of the FPCs on side A directly face that of the FPCs on side B, as illustrated in FIG. 6, during splicing of the two display screens, the FPCs of the two display screens only need to be coupled together through FPC connectors 40, so that after the two same display screens are spliced together, the FPCs of the two display screens can be completely hidden on the back surface of the display screens. In this way, the gap between the two display screens can be minimized and even seamless splicing of the two display screens can be achieved. In addition, the FPCs of the two display screens can be coupled to each other to realize communication.

It should be noted that although the above implementation illustrates that the FPC has the semi-rectangular structure, it can be understood that FPCs of other shapes are also within the protection scope of the disclosure, such as a FPC of the semicircular ring, square, or parabolic shape in the above implementations, shall fall within the protection scope of the disclosure.

Furthermore, although the disclosure only illustrates that the FPCs are merely disposed on a side edge or two side edges of the display screen, the protection scope of the disclosure is not limited thereto. In order to make the display screen communicate with other display screens or control terminals, FPCs corresponding to signal lines can be provided on three side edges or four side edges of the display screen, which all shall fall within the protection scope of the disclosure.

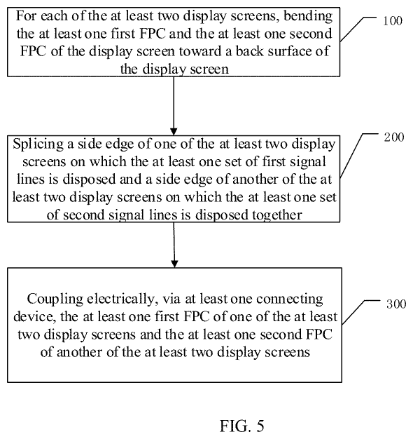

FIG. 5 is a flow chart illustrating a splicing method for a spliced display screens according to implementations of the disclosure. As illustrated in FIG. 5, the method begins at block 100.

At block 100, for each of two display screens, first FPCs and second FPCs of the display screen are respectively bent toward a back surface of the display screen. In one example, two display screens described above are selected, and all the FPCs of each display screen are bent to the back surface of the display screen by 180° to hide all the FPCs.

At block 200, a side edge of one of the two display screens on which multiple sets of first signal lines are disposed and a side edge of the other of the two display screens on which multiple sets of second signal lines are disposed are spliced together. In one example, side edges of two display screens on which staggered signal lines are disposed are coupled together. Since the FPCs are bent backwards, after the display screens are spliced, the FPCs are completely invisible from the front of the display screen, which can minimize the gap between the two display screens and even achieve seamless splicing of the two display screens.

At block 300, the first FPCs of one of the two display screens are electrically coupled with the second FPCs of another of the two display screens through connecting devices respectively. In one example, a FPC connector is used to connect two corresponding FPCs together to realize the communication between the two display screens, which also facilitates the layout of lines and reduces the length of the lines when multiple display screens are spliced. The FPC connector is generally cooperated with signal transmission components such as the FPC or a flexible flat cable (FFC) to transfer the signal from one end to the other end, so as to achieve signal transmission.

The display screens spliced by means of this method can realize the data transmission between adjacent display screens and facilitate the layout of the lines to be suitable for large-size and super-size spliced display screens. In addition, after the FPCs are folded, small gaps or seamless splicing between the display screens can be achieved.

It should be noted that although the foregoing merely illustrates splicing of two display screens, the disclosure is not limited thereto, and the splicing of other numbers of display screens also falls within the protection scope of the disclosure.

Implementations of the disclosure further provide a spliced display screen. As illustrated in FIG. 6, the spliced display screen is a display screen spliced by means of the above splicing method. That is, the spliced display screen is achieved by splicing multiple display screens, where each of the multiple display screens is provided with the above-mentioned FPCs on both side edges of the display screen, which can realize the data transmission between adjacent display screens and facilitate the layout of the lines to be suitable for large-size and super-size spliced display screens. In addition, after the FPCs are folded, small gaps or seamless splicing between the display screens can be achieved. Furthermore, since the FPCs on the two display screens each have the same shape, after the FPCs are coupled to each other, data lines from one display screen to the other display screen may also each have the same length, which is convenient for layout of lines.

The foregoing merely illustrates some implementations of the disclosure, and does not limit the scope of the patent of the disclosure. Any equivalent structure or equivalent flow transformation made on the basis of contents of the description and the accompanying drawings of the disclosure, or directly or indirectly applied in other related technical fields, are similarly included in the protection scope of the patent of the disclosure.

What is claimed is:

1. A display screen, comprising:
at least one first flexible printed circuit (FPC); and
a substrate, wherein the substrate is provided with at least one set of first signal lines on a side edge of the substrate, wherein each set of first signal lines is coupled with a first connecting portion of a corresponding first FPC, and for each first FPC, a second connecting portion of the first FPC faces the side edge of the substrate where the at least one set of first signal lines is disposed.

2. The display screen of claim 1, wherein the substrate is provided with at least one set of second signal lines on another side edge of the substrate opposite to the side edge where the at least one set of first signal lines is disposed, wherein the at least one set of second signal lines is coupled with at least one second FPC, and for each second FPC, the second FPC has a first connecting portion coupled with a corresponding set of second signal lines and a second connecting portion facing the another side edge of the substrate where the at least one set of second signal lines is disposed.

3. The display screen of claim 2, wherein the first FPC and the second FPC each have a U shape.

4. The display screen of claim 2, wherein the first FPC and the second FPC each have a semicircular shape.

5. The display screen of claim 2, wherein the first FPC and the second FPC each have a semi-rectangular shape.

6. The display screen of claim 2, wherein for each set of first signal lines, a central axis of a line-outlet position of the set of first signal lines and a central axis of a line-outlet position of the at least one set of second signal lines are parallel to one another.

7. The display screen of claim 6, wherein for each second FPC, a central axis of the second connecting portion of the second FPC coincides with that of the second connecting portion of one of two first FPCs adjacent to the second FPC.

8. A spliced display screen, comprising at least two display screens, wherein for each of the at least two display screens, the display screen comprises:
at least one first flexible printed circuit (FPC);
at least one second FPC; and
a substrate, wherein the substrate is provided with at least one set of first signal lines on a side edge of the substrate and at least one set of second signal lines on another side edge of the substrate opposite to the side edge where the at least one set of first signal lines is disposed, wherein
each set of first signal lines is coupled with a first connecting portion of a corresponding first FPC, and each set of second signal lines is coupled with a first connecting portion of a corresponding second FPC;
for each first FPC, a second connecting portion of the first FPC faces the side edge of the substrate where the at least one set of first signal lines is disposed, and for each second FPC, a second connecting portion of the second FPC faces the another side edge of the substrate where the at least one set of second signal lines is disposed; and
the at least one first FPC in one of the at least two display screens is electrically coupled to the at least one second FPC in another of the at least two display screens.

9. The spliced display screen of claim 8, wherein the first FPC and the second FPC each have a U shape.

10. The spliced display screen of claim 8, wherein the first FPC and the second FPC each have a semicircular shape.

11. The spliced display screen of claim 8, wherein the first FPC and the second FPC each have a semi-rectangular shape.

12. The spliced display screen of claim 8, wherein for each display screen, a central axis of a line-outlet position of each set of first signal lines and a central axis of a line-outlet position of the at least one set of second signal lines are parallel to one another.

13. The spliced display screen of claim 8, wherein for each display screen, a central axis of the second connecting portion of each second FPC coincides with that of the second connecting portion of one of two first FPCs adjacent to the second FPC.

14. The spliced display screen of claim 8, wherein the at least one set of first signal lines are evenly arranged on the side edge of the substrate and the at least one set of second signal lines are evenly arranged on another side edge of the substrate.

15. A splicing method for a spliced display screen, comprising:
for each of at least two display screens, bending at least one first FPC and at least one second FPC of the display screen toward a back surface of the display screen;
splicing a side edge of one of the at least two display screens on which at least one set of first signal lines is disposed and a side edge of another of the at least two display screens on which at least one set of second signal lines is disposed together; and
coupling electrically, via at least one connecting device, the at least one first FPC of one of the at least two display screens and the at least one second FPC of another of the at least two display screens.

16. The splicing method of claim 15, wherein the at least one first FPC and the at least one second FPC of the display screen are bent to the back surface of the display screen by 180°.

17. The splicing method of claim 15, wherein the first FPC has a same shape as the second FPC.

18. The splicing method of claim 15, wherein for each display screen, a central axis of a line-outlet position of each set of first signal lines and a central axis of a line-outlet position of the at least one set of second signal lines are parallel to one another.

19. The splicing method of claim 15, wherein for each display screen, a central axis of the second connecting portion of each second FPC coincides with that of the second connecting portion of one of two first FPCs adjacent to the second FPC.

20. The splicing method of claim 15, wherein the at least one set of first signal lines are evenly arranged on a side edge of the substrate and the at least one set of second signal lines are evenly arranged on another side edge of the substrate opposite to the side edge where the at least one set of first signal lines is disposed.
